(19) United States
(12) Patent Application Publication
(10) Pub. No.: US 2025/0079208 A1
(43) Pub. Date: Mar. 6, 2025

(54) INSPECTION SYSTEM AND METHOD FOR SUPPORTING BEAM OF SUBSTRATE CARRIER

(71) Applicant: Gudeng Precision Industrial co., LTD, New Taipei City (TW)

(72) Inventors: MING-CHIEN CHIU, New Taipei City (TW); YUNG-CHIN PAN, New Taipei City (TW); MENG-SIAN WU, New Taipei City (TW); TZU-NING HUANG, New Taipei City (TW)

(21) Appl. No.: 18/798,871

(22) Filed: Aug. 9, 2024

Related U.S. Application Data
(60) Provisional application No. 63/536,603, filed on Sep. 5, 2023.

(51) Int. Cl. H01L 21/67

(52) U.S. Cl. CPC H01L 21/67259

(57) ABSTRACT

An inspection system and an inspection method for at least one supporting beam include the steps of setting a lateral surface of one supporting beam as a reference point for detecting an offset amount; applying a predetermined force respectively to the supporting beams in sequence in a moving direction; detecting the offset amount of the supporting beam as applied by the predetermined force; and, acquiring an inspection result by a calculation based on the reference point and the offset amount. The inspection system includes a pushing member, a driving module, and an offset sensor. The pushing member is used for applying a predetermined force to the supporting beam. The driving module connects to the pushing member for driving the pushing member to move toward the supporting beam. The offset sensor is used for detecting an offset amount of the supporting beam as applied by the predetermined force.

### RELATED APPLICATIONS

This application claims priority to U.S. Provisional Patent Application, No. US 63/536,603, by CHIU, et al., titled “Inspection System for Central Beam in FOUP,” filed on Sep. 5, 2023, which is hereby incorporated by reference in their entirety.

### BACKGROUND OF THE INVENTION

### Technical Field

The present invention relates to an inspection system and method for supporting beam. More particularly, the present invention relates to an inspection system and method for supporting beam for using in a substrate carrier.

### Description of Related Art

In the technical field of semiconductor manufacturing, there exists a need for transporting semiconductor substrates. It is known to use large substrate carriers such as front opening unified pods (FOUPs) or the like to contain and transport multiple substrates. In such a substrate carrier, multiple supporting pieces are equidistantly arranged on two internal sidewalls of the carrier, so as to support the substrates. However, with the increment in the size of the substrates, the manner of supporting the substrates from two sidewalls alone can no longer be sufficient to meet the requirement of bearing the weight of the substrates. The industry then came up with the idea of adding a central beam structure in the carrier to provide better support.

The central beam structure includes multiple carbon rods that are arranged at equal intervals and used as supports for the semiconductor substrates respectively. In practical use, before such a large substrate carrier can be used to accommodate the substrates, the carbon rods need to be measured to determine whether any of the cardon rods is tilted or deviated from a central line. One known method of measuring the carbon rods is to use a manual measuring tool to measure the offset of each carbon rod relative to the central line. However, there are some drawbacks to this measuring method. First, the measuring tool itself and the probe heads thereon need to be calibrated prior to actual measurement, usually by a calibration tool. The calibration process takes a considerable amount of time. After the calibration is complete, the calibration tool needs to be removed from the measuring platform so the calibrated measuring tool can be used to perform actual measurement on the substrate carrier product. Second, when the measuring tool is installed on the measuring platform, the measurement parameters need to be adjusted manually according to different substrate carriers. If the size or specification of the measuring tool is found to be incorrect, the measuring tool needs to be removed from the measuring platform to perform further adjustments. The whole process is complicated and lacks efficiency.

### SUMMARY

In view of the above-mentioned problems, the present invention is to provide an inspection system and inspection method for one or more supporting beams of a substrate carrier, allowing a prompt acquisition of the offset amount of the supporting beam which simplifies the inspection process and increases the efficiency.

According to one aspect of the invention, an inspection system for inspecting at least one supporting beam of a substrate carrier is provided. The inspection system includes a pushing member, a driving module, and an offset sensor. The pushing member is sued for applying a predetermined force to the supporting beam. The driving module is connected to the pushing member for driving the pushing member to move toward the supporting beam, thereby applying the predetermined force to the supporting beam. The offset sensor is disposed on one side of the supporting beam for detecting an offset amount of the supporting beam as applied by the predetermined force.

In one embodiment, the inspection system further includes a lifting module. The lifting module is connected to a base which the pushing member, the driving module, and the offset sensor are disposed thereon. The lifting module is used for moving the base vertically.

In one embodiment, the inspection system inspection system includes multiple supporting beams that are arranged in parallel, and the offset sensor sequentially detects plural offset amounts of the supporting beams in a moving direction. The base is moved by the lifting module at least in the moving direction.

In one embodiment, the inspection system further includes a control module. The control module communicates with the driving module and the offset sensor to operate them. The inspection system includes multiple supporting beams that are arranged in parallel, and the control module sets a lateral surface of an uppermost one or a lowermost one of the supporting beams as a reference point for detecting the offset amount and the reference point is an offset detecting standard for the rest of the supporting beams.

In one embodiment, after the predetermined force is applied to one of the supporting beams by the pushing member, the offset sensor detects the offset amount of the supporting beam, and the control module acquires an inspection result by calculating a lateral offset of the lateral surface of the supporting beam based on the offset amount and the reference point.

In one embodiment, the supporting beam has a connecting end for connecting to a backbone, a middle section, and a suspension end in opposite to the connecting end and the offset sensor is in proximity to the connecting end, the middle section, or the suspension end.

According to another aspect of the invention, an inspection method for at least one supporting beam is provided. The inspection method includes the steps of: setting a lateral surface of one of multiple supporting beams as a reference point for detecting an offset amount, the supporting beams being arranged in parallel; applying a predetermined force respectively to the supporting beams in sequence in a moving direction; detecting the offset amount of the supporting beam as applied by the predetermined force; and acquiring an inspection result by a calculation based on the reference point and the offset amount.

In one embodiment, the inspection method further includes the steps of: driving, by a driving module, a pushing member to move toward the supporting beam to apply the predetermined force;

detecting, by an offset sensor, the reference point and the offset amount; and acquiring, by a control module, the inspection result by the calculation based on the reference point and the offset amount.

In one embodiment, the inspection method further includes the steps of: moving, by a lifting module, the driving module and the offset sensor in the moving direction from one of the supporting beams to another.

In one embodiment, in the step of detecting by the offset sensor, multiple offset sensors are arranged in proximity to a connecting end, a middle section, a suspension end, and/or any other location of the supporting beam.

According to the disclosure of the embodiments of the invention, the predetermined force is applied to the supporting beam and the offset amount of the supporting beam is detected as it is applied by the predetermined force. The inspection method therefore can be simplified and the efficiency can be increased. In some embodiments, the offset amount of another supporting beam can be acquired by moving the offset sensor, so the supporting beams can be inspected in sequence. The problems like complicated process and lacking efficiency can be avoided.

### BRIEF DESCRIPTION OF DRAWINGS

The invention can be more fully understood by reading the following detailed description of the embodiment, with reference made to the accompanying drawings as follows:

FIG. 1 is a schematic diagram of an inspection system of at least one supporting beam according to one embodiment of the invention;

FIG. 2 is a schematic diagram of a top view of the inspection system before the predetermined force is applied;

FIG. 3 is a schematic diagram of a top view of the inspection system as the predetermined force is applied;

FIG. 4 is a schematic diagram of the offset sensor detecting the first offset amount;

FIG. 5 is a schematic diagram of the offset sensor and the pushing member being located beside the first supporting beam;

FIG. 6 is a schematic diagram of the offset sensor and the pushing member being located beside a second supporting beam;

FIG. 7 is a schematic diagram of the offset sensor detecting a second offset amount;

FIG. 8 is a schematic diagram of the offset sensor detecting several offset amounts;

FIG. 9 is a schematic diagram of the inspection system including multiple offset sensors;

FIG. 10 is a block diagram of an inspection system according to another embodiment of the invention;

FIG. 11 is a flow chart of an inspection method according to one embodiment of the invention;

FIG. 12 is a flow chart of an inspection method according to another embodiment of the invention; and

FIG. 13 is a flow chart of an inspection method for the second supporting beam.

### DETAILED DESCRIPTION

The inspection system and inspection method for supporting beam of a substrate carrier according to the embodiments of the invention apply a predetermined force to the supporting beam and detect an offset amount of the supporting beam as it is applied by the predetermined force. The complicated steps of using the manual measuring tool can be omitted and thus the inspection method can be simplified. This achieves a more convenient and faster inspection process. Further, the predetermined force can be adjusted according to different product needs, which enhances the flexibility of the inspection system and method. The offset amount of the supporting beam can be acquired promptly and the inspection efficiency can be improved.

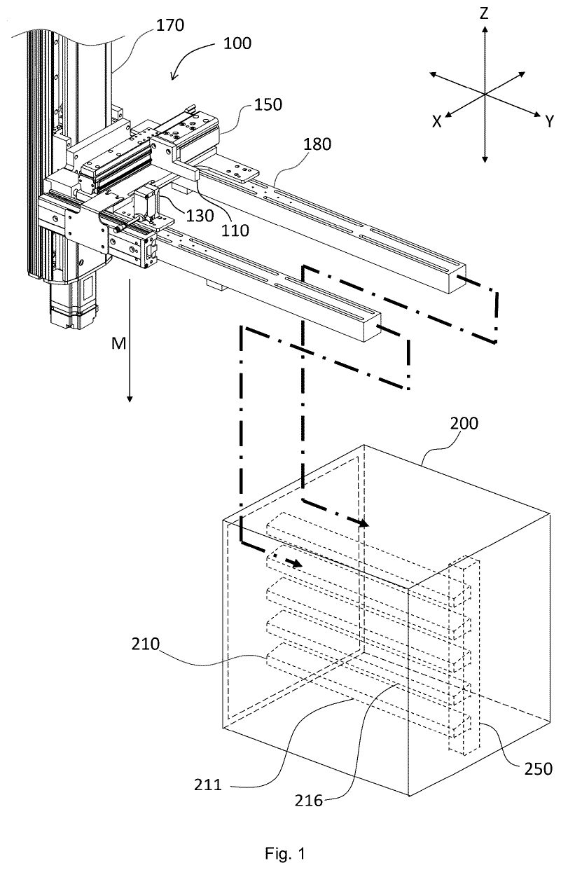

Please refer to FIG. 1, which is a schematic diagram of an inspection system of at least one supporting beam according to one embodiment of the invention. The inspection system for inspecting at least one supporting beam 100 (will be referred to as the inspection system 100) is used to inspect at least one supporting beam 210 of a substrate carrier 200. The substrate carrier 200 includes multiple supporting beams 210, and one end of each supporting beam 210 is connected to a backbone 250 thereby connecting in the substrate carrier 200. The other end of each supporting beam 210 is suspended inside the substrate carrier 200. The substrate carrier 200, the supporting beams 210, the backbone 250, elements like semiconductor substrates contained in the substrate carrier 200, and their structure and configuration are not limited in the invention. The supporting beams 210 are the workpiece to-be-inspected by the inspection system 100.

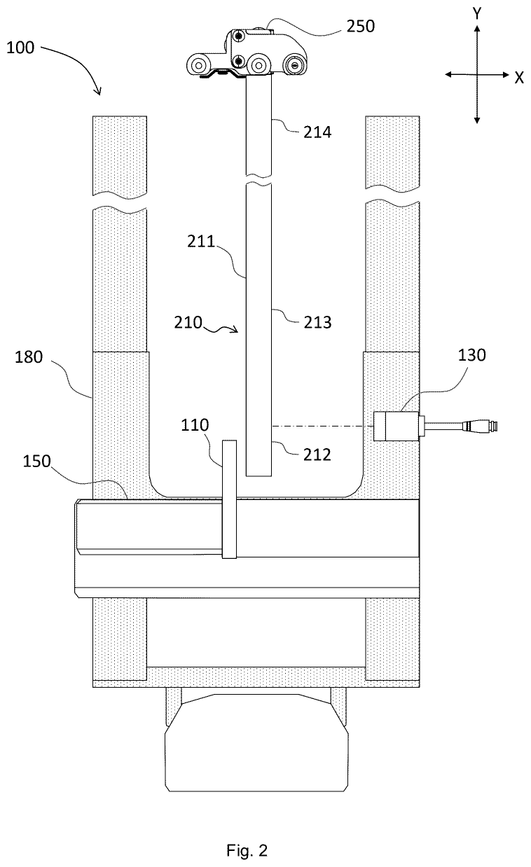

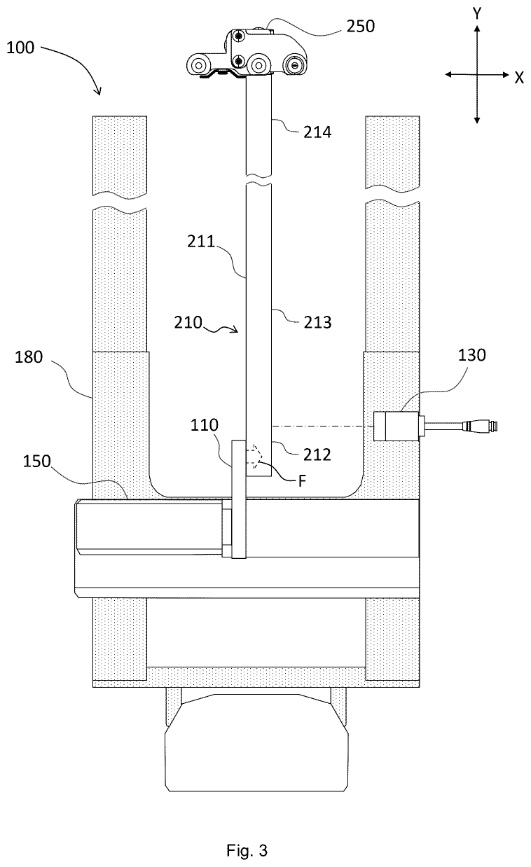

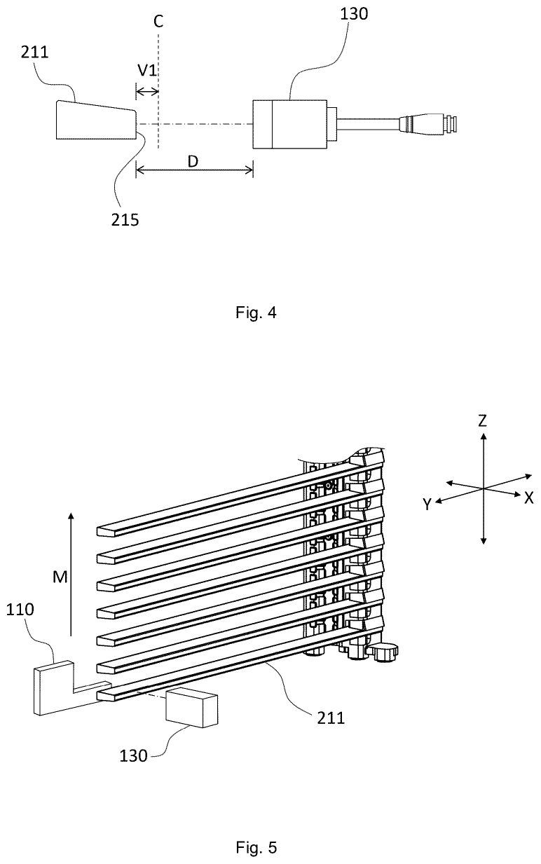

Since there are multiple supporting beams 210 disposed in the substrate carrier 200, the mechanism of acquiring a first offset amount of a first supporting beam is elaborated. Please refer to FIG. 1 to FIG. 4. FIG. 2 is a schematic diagram of a top view of the inspection system before the predetermined force is applied. FIG. 3 is a schematic diagram of a top view of the inspection system as the predetermined force is applied. FIG. 4 is a schematic diagram of the offset sensor detecting the first offset amount. The inspection system 100 includes a pushing member 110, a driving module 150, and an offset sensor 130. The pushing member 100 is used for applying the predetermined force F to the supporting beam 210; to be more specific, the force F is applied to the first supporting beam 211 here in FIGS. 2 to 4. As shown in FIGS. 2 and 3, the pushing member 110 applies the predetermined force F to the first supporting beam 211 in the X axial direction. After being pushed by the force F, the first supporting beam 211 may deviate from its original position. The inspection system 100 is used to inspect whether the deviation of each supporting beam 210 exceeds a predetermined distance. Exemplarily, the purpose of the predetermined force F is to reproduce a force applied by an operator while he/she accidentally touches or bumps against the supporting beam 210. The inspection system 100 is to inspect whether the supporting beam 210 deviates under such situation and further determine whether the deviation exceeds the predetermined distance; if yes, the supporting beam 210 needs to be recalibrated.

The driving module 150 is connected to the pushing member 110 for driving the pushing member 110 to move toward the first supporting beam 211, thereby applying the predetermined force F to the first supporting beam 211. The offset sensor 130 is disposed on one side of the first supporting beam 211 for detecting the offset amount of the first supporting beam 211 as applied by the force F. As shown in FIG. 4, the offset amount is exemplified by a first offset amount V1 here. In the present embodiment, the first supporting beam 211 is the lowermost one of these supporting beams 210; however, the invention is not limited thereto, the first supporting beam 211 can also be the uppermost one or any intermediate one, based on actual inspection needs.

The offset sensor 130 is used to measure a distance D from the sensor 130 to a lateral surface 215 of the first supporting beam 211. The offset sensor 130 can be exemplified by IR proximity sensor or any other sensors that use suitable distance measuring techniques such as ultrasonic. As long as the distance D can be acquired, the technology and type of the sensor are not limited here in the invention. The lateral surface 215 of the uppermost one or the lowermost one of the supporting beams 210 is set as a reference point C for detecting the offset amount and the reference point C is an offset detecting standard for the rest of the supporting beams 210. Here in the present embodiment, the position of the lateral surface 215 of the first supporting beam 211 is set as the reference point C. After the driving module 150 moves the pushing member 110 to apply the predetermined force F to one of the supporting beams 210 (the first supporting beam 211 here), the first offset amount V1 of the first supporting beam 210 applied by the force F can be detected. Then an inspection result can be acquired by calculating a lateral offset of the lateral surface 215 of the first supporting beam 211 based on the first offset amount V1 and the reference point C.

After the predetermined force F is applied to the first supporting beam 211 by the inspection system 100, the first offset amount V1 of the first supporting beam 211 is detected by the offset sensor 130, and therefore the reference point C is acquired, the inspection on the first supporting beam 211 is completed. The system 100 then moves on to the inspection of another supporting beam 210.

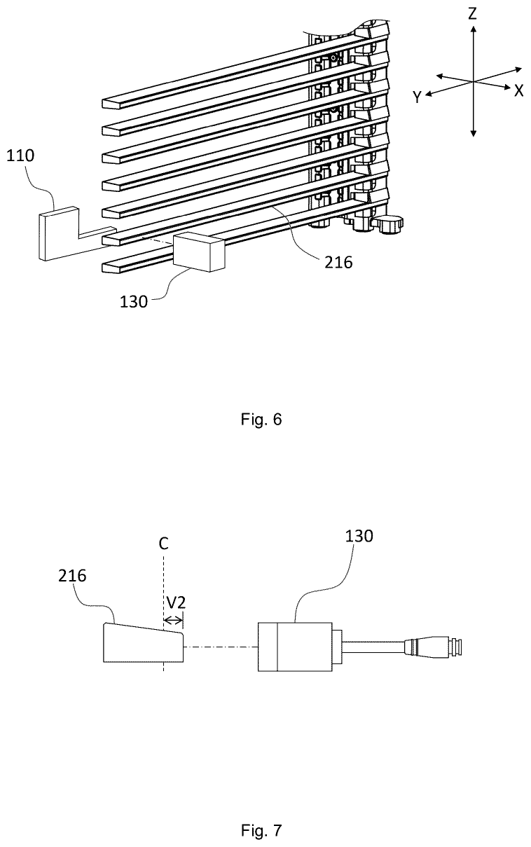

Please refer to FIG. 1 and FIGS. 5 to 7. FIG. 5 is a schematic diagram of the offset sensor and the pushing member being located beside the first supporting beam. FIG. 6 is a schematic diagram of the offset sensor and the pushing member being located beside a second supporting beam. FIG. 7 is a schematic diagram of the offset sensor detecting a second offset amount. In the present embodiment, the inspection system 100 further includes a lifting module 170 which is connected to a base 180 and the pushing member 110, the driving module 150, and the offset sensor 130 are disposed on the base 180 as shown in FIG. 1. The lifting module 170 is used for moving the base 180 vertically; to be more specific, moving up and down in the Z axial direction of FIG. 5 and FIG. 6.

Since there are two or more supporting beams 210 that are arranged in parallel, the offset sensor 130 can sequentially detect multiple offset amounts of the supporting beams in a moving direction M as shown in FIG. 5. The base 180 (shown in FIG. 3) is moved by the lifting module 170 at least in the moving direction M; that is, parallel to the Z axial direction. In the present embodiment, the offset sensor 130 and the pushing member 110 are exemplified by moving to a second supporting beam 216 adjacent to the first one 211 as shown in FIG. 6. Therefore, a second offset amount V2 (shown in FIG. 7) of the second supporting beam 216 can be detected. The steps of applying the force and detecting the offset amount by the inspection system 100 are the same as those to the first supporting beam 211 and will not be repeated. After the second offset amount V2 is acquired, whether the deviation of the second supporting beam 216 exceeds the predetermined distance or not can be determined based on the second offset amount v2 and the reference point C.

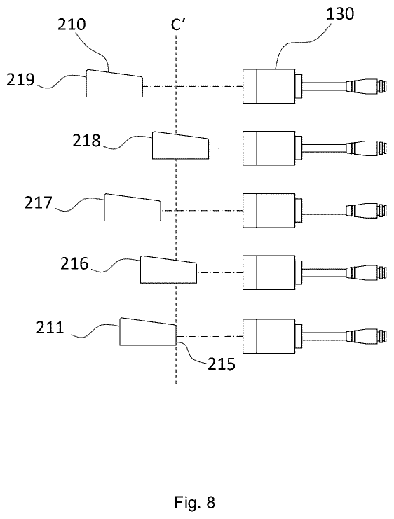

Please refer to FIG. 8, which is a schematic diagram of the offset sensor detecting several offset amounts. In one embodiment, after the first offset amount V1 (shown in FIG. 4) is detected, the inspection system 100 sets the first offset amount V1 as “0”. The lateral surface 215 of the first supporting beam 211 is set as the reference point C. The reference point C is the offset detecting standard for the rest of the supporting beams 210. While inspecting the second supporting beam 216, the inspection system 100 determines whether the second supporting beam 216 deviates exceed the predetermined distance based on the reference point C. Here the deviation amount is the second offset amount V2 (shown in FIG. 7). Similarly, while inspecting the following third, fourth, and fifth supporting beams 217, 218, & 219 and other subsequent supporting beams 210, whether their respective offset amount exceeds the predetermined distance can be determined based on the reference point C. When any one of the supporting beams 210 deviates beyond the predetermined distance, it means that supporting beam 210 needs to be recalibrated.

Regarding the configuration of the offset sensor 130, different embodiments can apply. As shown in FIGS. 2 and 3, only one offset sensor 130 is included in the inspection system 100 of the present embodiment. The first supporting beam 211 has a connecting end 214 for connecting to the backbone 250, a middle section 213, and a suspension end 212 in opposite to the connecting end 214. The offset sensor 130 is in proximity to the suspension end 212 in the present embodiment. Of course, one skilled in the art would understand that the offset sensor 130 can also be arranged in proximity to the connecting end 214 or the middle section 213 to detect different offset amounts at different parts of the first supporting beam 211. As for detecting the second supporting beam 216 or the other supporting beams 210, the offset sensor 130 may have the same detecting configuration; for brevity, the details will not be repeated here.

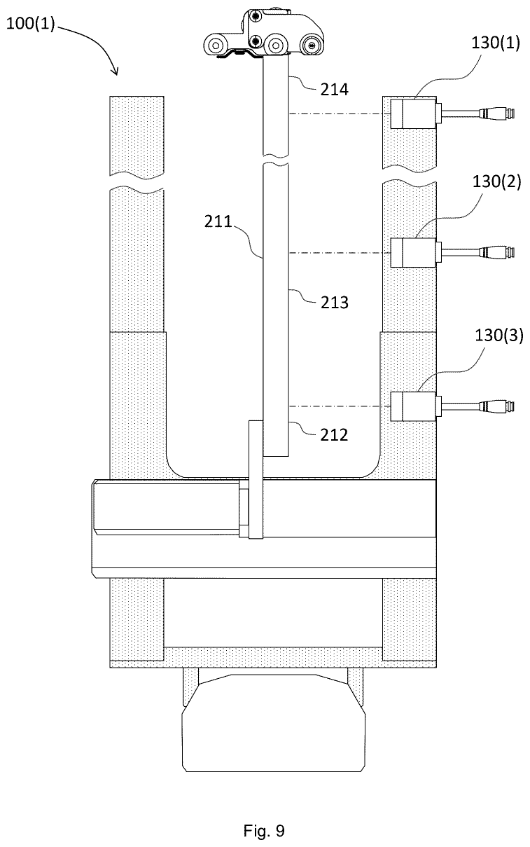

On the other hand, two or more offset sensors 130 can be used. Please refer to FIG. 9, which is a schematic diagram of the inspection system including multiple offset sensors. The inspection system 100(1) includes three offset sensors 130(1), 130(2), and 130(3). These offset sensors 130(1), 130(2), and 130(3) are respectively located in proximity to the connecting end 214, the middle section 213, and the suspension end 212 of the first supporting beam 211. Different offset amounts at different parts of the first supporting beam 211 can be detected at the same time or in sequence. The accuracy of inspection can be increased therefrom. In addition to the above elaborated locations, the offset sensors 310(1), 310(2), and 310(3) can be respectively put at any desirable locations near the first supporting beam 211.

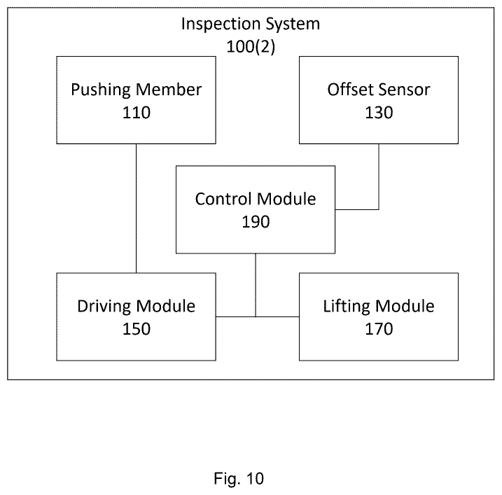

Please refer to FIG. 10, which is a block diagram of an inspection system according to another embodiment of the invention. The inspection system 100(2) includes the pushing member 110, the driving module 150, the offset sensor 130, and the lifting module 170 that are similar to those of the previously described inspection system 100. The inspection system 100(2) of the present embodiment further includes a control module 190. The control module 190 communicates with the driving module 150 and the offset sensor 130 to operate them. The control module 190 sets the lateral surface 215 of the uppermost one or the lowermost one of the parallelly arranged supporting beams 210 as the reference point C for detecting the offset amount, and the reference point C is set as the offset detecting standard for the rest of the supporting beams 210. After the predetermined force F is applied to one of the supporting beams 210 by the pushing member 110, the offset sensor 130 detects the offset amount of the supporting beam 210, and the control module 190 acquires the inspection result by calculating the lateral offset of the lateral surface 215 of the supporting beam 210 based on the offset amount and the reference point C. The control module 190 can be exemplified by and not limited to central processing unit (CPU) or I/O controller. The control module 190 is used to control the movement and the magnitude of the force of the driving module 150, thereby controlling the magnitude of the predetermined force F applied to the supporting beam 210 by the pushing member 110. Additionally, the control module 190 also controls the movement of the lifting module 170, so the pushing member 110 and the offset sensor 130 can be moved to the location corresponding to a specific to-be-inspected supporting beam 210.

In the embodiments relating to FIGS. 4 to 7, the control module 190 can be used to determine whether the second offset amount V2 of the second supporting beam 216 exceeds the predetermined distance based on the reference point C corresponding to the position of the lateral surface 215 of the first supporting beam 211.

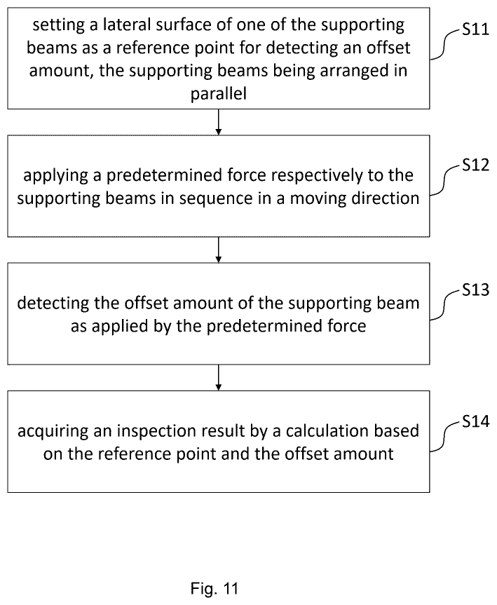

The inspection method for at least one supporting beam according to embodiments of the invention is detailed below. Please refer to FIG. 11, which is a flow chart of an inspection method according to one embodiment of the invention. The inspection method of the embodiment can be implemented to the aforementioned inspection system 100, and the components and element reference numbers of the inspection system 100 are used here. After the substrate carrier 200 is disposed in the inspection system 100, the inspection system 100 may begin the inspection. The inspection method includes the following steps.

First, in step S11, a lateral surface of one of the supporting beams is set as the reference point C for detecting an offset amount and the supporting beams are arranged in parallel.

Then in step S12, a predetermined force is applied respectively to the supporting beams in sequence in a moving direction.

Further in step S13, the offset amount of the supporting beam as applied by the predetermined force is detected.

In step S14, an inspection result is acquired by a calculation based on the reference point C and the offset amount.

To be more specific, the inspection method includes the steps of: driving, by the driving module 150, the pushing member 110 to move toward the supporting beam to apply the predetermined force F; detecting, by the offset sensor 130, the reference point C and the offset amount; and, acquiring, by the control module 190, the inspection result by the calculation based on the reference point C and the offset amount. In the inspection method, the driving module 150 and the offset sensor 130 are moved by the lifting module 170 from one of the supporting beams to another in the moving direction. In the step of detecting by the offset sensor 130, one or more offset sensors 130 can be used for example, and the offset sensors 130 are arranged in proximity to the connecting end 214, the middle section 213, the suspension end 212, and/or any other desirable locations of the supporting beam 210.

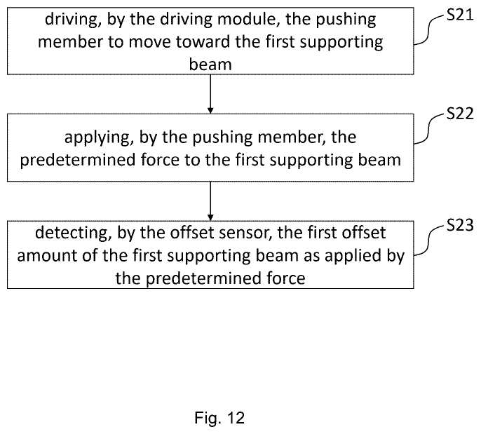

Please refer to FIG. 12, which is a flow chart of an inspection method according to another embodiment of the invention. The inspection method can also be implemented to the aforementioned inspection system 100.

First, in step S21, the pushing member 110 is driven by the moving module 150 to move toward the first supporting beam 211.

Then in step S22, the predetermined force F is applied to the first supporting beam 211 by the pushing member 210.

Afterwards in step S23, the first offset amount V1 of the first supporting beam 211 as applied by the predetermined force 211 is detected by the offset sensor 130.

After the first offset amount V1 has been acquired, it is then set as the reference point C for detecting other offset amounts, and the reference point C is regarded as the offset detecting standard for the rest of the supporting beams.

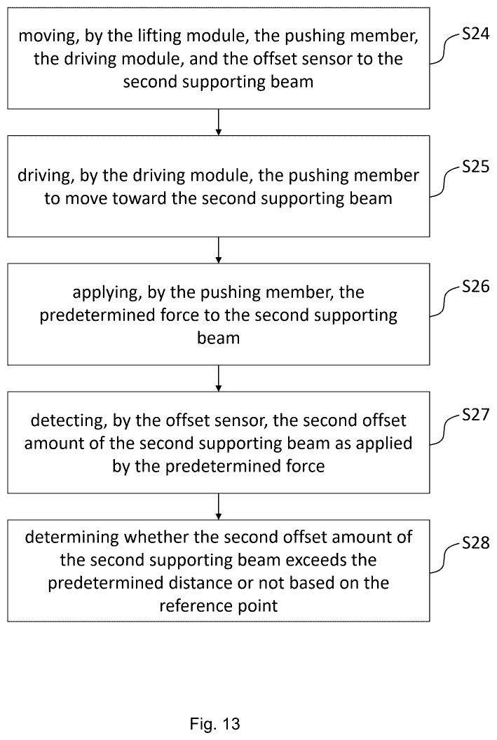

When the inspection on the first supporting beam 211 is completed, the inspection method moves on to the next supporting beam 210. Please refer to FIG. 13, which is a flow chart of an inspection method for the second supporting beam. In the present embodiment, steps S24 to S27 are performed after step S23.

In step S24, the pushing member 110, the driving module 150, and the offset sensor 130 are moved to the second supporting beam 216 by the lifting module 170.

Then in step S25, the pushing member 110 is driven to move toward the second supporting beam 216 by the driving module 150.

Further in step S26, the predetermined force F is applied to the second supporting beam 216 by the pushing member 110.

Afterwards, in step S27, the second offset amount V2 of the second supporting beam 216 as applied by the predetermined force F is detected by the offset sensor 130.

The inspection method of the present embodiment is concluded with steps S28 in which whether the second offset amount V2 of the second supporting beam 216 exceeds the predetermined distance or not is determined, exemplarily by the control module 190, based on the reference point C.

The above-described embodiments of the invention allow for the inspection of the supporting beam by applying the predetermined force through the pushing member. This facilitates the prompt acquisition of the offset amount of the supporting beam and improves the inspection efficiency. In some embodiments, the pushing member and one or more of the offset sensors are moved to another supporting beam by the lifting module to perform inspection, allowing for the inspection of multiple supporting beams in a brief period without using the manual measuring tool. This simplifies the inspection method and achieves a more convenient and faster inspection process. Additionally, since the predetermined force can be adjusted based on different product needs, the flexibility of the inspection system and method can be increased as well.

While the present invention has been disclosed above through a number of embodiments, those embodiments are not intended to be restrictive of the scope of the invention. A person who is skilled in the art will be able to make various changes or modifications to the disclosed embodiments without departing from the spirit or scope of the invention. The scope of the patent protection sought by the applicant is defined by the appended claims.

What is claimed is:

1. An inspection system for inspecting at least one supporting beam of a substrate carrier, comprising:
a pushing member for applying a predetermined force to said supporting beam;
a driving module connecting to said pushing member for driving said pushing member to move toward said supporting beam, thereby applying said predetermined force to said supporting beam; and
an offset sensor disposed on one side of said supporting beam for detecting an offset amount of said supporting beam as applied by said predetermined force.

2. The inspection system according to claim 1, further comprising:
a lifting module connecting to a base which said pushing member, said driving module, and said offset sensor are disposed thereon, wherein said lifting module is used for moving said base vertically.

3. The inspection system according to claim 2, wherein said inspection system comprises a plurality of said supporting beams that are arranged in parallel and said offset sensor sequentially detects a plurality of said offset amounts of said supporting beams in a moving direction, wherein said base is moved by said lifting module at least in said moving direction.

4. The inspection system according to claim 1, further comprising:
a control module communicating with said driving module and said offset sensor to operate them;
wherein said inspection system comprises a plurality of said supporting beams that are arranged in parallel and said control module sets a lateral surface of an uppermost one or a lowermost one of said supporting beams as a reference point for detecting said offset amount and said reference point is an offset detecting standard for the rest of said supporting beams.

5. The inspection system according to claim 4, wherein after said predetermined force is applied to one of said supporting beams by said pushing member, said offset sensor detects said offset amount of said supporting beam, and said control module acquires an inspection result by calculating a lateral offset of said lateral surface of said supporting beam based on said offset amount and said reference point.

6. The inspection system according to claim 1, wherein said supporting beam has a connecting end for connecting to a backbone, a middle section, and a suspension end in opposite to said connecting end and said offset sensor is in proximity to said connecting end, said middle section, or said suspension end.

7. An inspection method for at least one supporting beam, comprising:
setting a lateral surface of one of a plurality of said supporting beams as a reference point for detecting an offset amount, said supporting beams being arranged in parallel;
applying a predetermined force respectively to said supporting beams in sequence in a moving direction;
detecting said offset amount of said supporting beam as applied by said predetermined force; and
acquiring an inspection result by a calculation based on said reference point and said offset amount.

8. The inspection method according to claim 7, further comprising:
driving, by a driving module, a pushing member to move toward said supporting beam to apply said predetermined force;
detecting, by an offset sensor, said reference point and said offset amount; and
acquiring, by a control module, said inspection result by said calculation based on said reference point and said offset amount.

9. The inspection method according to claim 8, further comprising:
moving, by a lifting module, said driving module and said offset sensor in said moving direction from one of said supporting beams to another.

10. The inspection method according to claim 8, wherein in said step of detecting by said offset sensor, a plurality of said offset sensors are arranged in proximity to a connecting end, a middle section, a suspension end, and/or any other location of said supporting beam.
